(19) United States
(12) Patent Application Publication
(10) Pub. No.: US 2015/0275351 A1
(43) Pub. Date: Oct. 1, 2015

(54) Evaporation Tool

(71) Applicant: Apple Inc., Cupertino, CA (US)

(72) Inventors: Jungmin Lee, Cupertino, CA (US); Jae Won Choi, Cupertino, CA (US); Jueng-Gil J. Lee, Cupertino, CA (US); Stephen S. Poon, San Jose, CA (US); John Z. Zhong, Cupertino, CA (US)

(21) Appl. No.: 14/501,541

(22) Filed: Sep. 30, 2014

Related U.S. Application Data
(60) Provisional application No. 61/973,337, filed on Apr. 1, 2014.

(51) Int. Cl. C23C 14/24; C23C 14/04

(52) U.S. Cl. CPC C23C 14/24; C23C 14/042

(57) ABSTRACT

An evaporation tool is provided that has an elongated evaporation source with elongated edges that run parallel to a longitudinal axis and shorter edges that run perpendicular to the longitudinal axis. The evaporation source has multiple evaporation sources formed by respective source orifices through which material is evaporated. An evaporation control structure is mounted to the evaporation source to enhance the directionality of evaporated material. A shadow mask is provided that has a rectangular frame for supporting a metal mask layer with a pattern of openings. The evaporation control structure ensures that the evaporated material from the source is evaporated towards the shadow mask. Angled walls attached to the elongated edges, a series of vertical walls that extend between the angled walls in the evaporation control structure, and aligned vertical wall extensions on the frame of the shadow mask are used to block evaporated material following angled trajectories.

This application claims the benefit of provisional patent application No. 61/973,337 filed Apr. 1, 2014, which is hereby incorporated by reference herein in its entirety.

### BACKGROUND

This relates generally to evaporation tools and, more particularly, to thermal evaporation tools for forming display pixel structures.

Electronic devices often include displays. For example, an electronic device may have an organic light-emitting diode display or other display with an array of display pixels. The display pixels may include emissive layers or other structures of different colors. For example, red, blue, and green pixel structures may be used in a display to present color images to a user.

Emissive layers and other structures in a display can be formed by evaporation. A shadow mask may be placed adjacent to a display substrate. The shadow mask may have an array of openings. The openings have a pattern that corresponds to a desired pattern for an array of colored pixels or other display pixel structures. Material to be deposited is heated until it evaporates and is deposited onto the substrate.

Some evaporators include a linear evaporation source that is translated across the shadow mask during evaporation operations. A customized horizontal correction plate may be used to help ensure even deposition from a linear array of orifices in the source. The correction plate may have an opening that runs along the length of the linear source. The opening has a shape that helps reduce hotspots along the linear source. However, angular variations in the material being deposited from different positions along the length of the linear source are not controlled and adversely affect deposition uniformity.

It would therefore be desirable to be able to provide improved evaporation tools and improved components such as displays formed using such evaporation tools.

### SUMMARY

An evaporation tool is provided that has an elongated evaporation source. The elongated evaporation source may have elongated edges that run parallel to a longitudinal axis and shorter edges that run perpendicular to the longitudinal axis. The evaporation source may have multiple evaporation sources extending along its longitudinal axis that are formed by respective source orifices through which material is evaporated. Evaporated material from the evaporation source may be used to form display pixel structures on a display substrate.

An evaporation control structure is mounted to the evaporation source to enhance the directionality of the evaporated material. A shadow mask is provided adjacent to the display substrate to pattern evaporated material that is being deposited on the display substrate. To ensure that the entire display substrate is covered with evaporated material, a positioner may translate the evaporation source relative to the shadow mask in a direction perpendicular to the longitudinal axis.

The shadow mask has a rectangular frame for supporting a metal mask layer with a pattern of openings. The evaporation control structure ensures that the evaporated material from the source is evaporated towards the shadow mask. Angled walls in the evaporation control structure are attached to the elongated edges. Vertical walls extend between the angled walls. The vertical walls may have upper edges that are aligned with the edges of corresponding vertical wall extensions attached to the frame of the shadow mask. The vertical walls and the vertical wall extensions divide the evaporation control structure into a series of separate sections each of which contains a different respective group of the source orifices. The walls are used to block evaporated material following trajectories that are angled with respect to vertical and thereby ensure that the evaporated material is directed towards the shadow mask and does not strike the shadow mask at oblique angles.

### BRIEF DESCRIPTION OF THE DRAWINGS

FIG. 1 is a diagram of an illustrative display in accordance with an embodiment.

FIG. 2 is a cross-sectional view of an illustrative display pixel in an organic light-emitting diode display in accordance with an embodiment.

FIG. 3 is a top view of an illustrative display with display pixels of different colors in accordance with an embodiment.

FIG. 4 is a cross-sectional side view of an illustrative evaporation tool in accordance with an embodiment.

FIG. 5 is a side view of an illustrative linear evaporation source with a plurality of discrete source elements such as orifices that are located at different locations along the longitudinal axis of the source in accordance with an embodiment.

FIG. 6 is a perspective view of an illustrative evaporation tool in accordance with an embodiment.

FIG. 7 is a side view of the illustrative evaporation tool of FIG. 6 in accordance with an embodiment.

FIG. 8 is a cross-sectional end view of an upper portion of an illustrative linear source divider wall in accordance with an embodiment.

### DETAILED DESCRIPTION

Material may be deposited on a target using an evaporation tool. The evaporation tool, which may sometimes be referred to as a vacuum thermal evaporation device, may deposit material in thin layers. Illustrative arrangements for using an evaporation tool to deposit colored organic materials onto a display substrate are sometimes described herein as an example. This is, however, merely illustrative. The evaporation tool may be used to deposit material onto any suitable target structure.

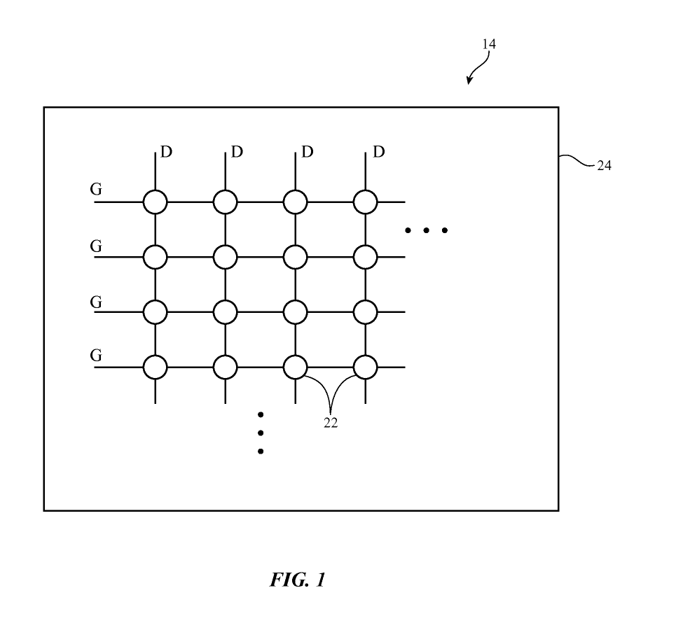

An illustrative display is shown in FIG. 1. As shown in FIG. 1, display 14 may include layers such as substrate layer 24. Layers such as substrate 24 may be formed from planar rectangular layers of material such as planar glass layers, planar polymer layers, composite films that include polymer and inorganic materials, metallic foils, etc.

Display 14 may have an array of display pixels 22 for displaying images for a user. The array of display pixels 22 may be formed from rows and columns of display pixel structures (e.g., display pixels formed from structures on display layers such as substrate 24). There may be any suitable number of rows and columns in the array of display pixels 22 (e.g., ten or more, one hundred or more, or one thousand or more).

During operation, display control circuitry asserts signals on gate lines G (sometimes referred to as scan lines) and on data lines D (sometimes referred to as source lines). These signals cause display pixels 22 to emit light and form images for a viewer. To provide display 14 with the ability to display color images, display pixels 22 may be provided in different colors. As an example, display pixels 22 may include red display pixels that emit red light, green display pixels that emit green light, and blue display pixels that display blue light. Other display pixel types may be used if desired. The use of red, green, and blue display pixels in display 14 is merely illustrative.

With one illustrative configuration, display 14 is an organic light-emitting diode display and display pixels 22 are each formed from a corresponding organic light-emitting diode. In color displays, display pixels 22 may include red organic light-emitting diodes, green light-emitting diodes, and blue light-emitting diodes (as an example). The color of light emitted by each organic light-emitting diode may be determined by the color of its organic emissive layer and/or a color filter element. Configurations in which display pixels 22 have emissive layers of different colors are described herein as an example.

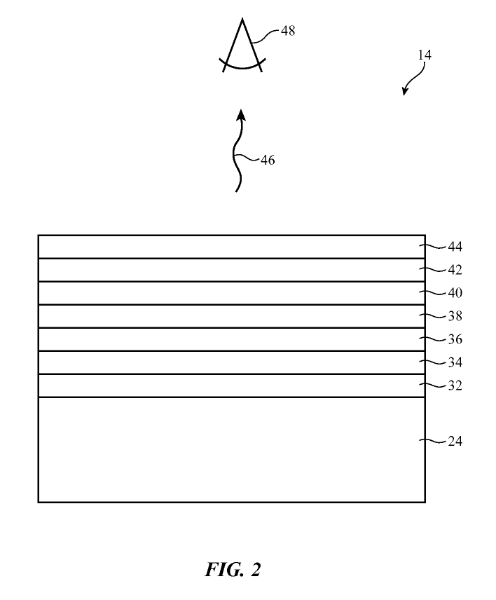

A cross-sectional side view of a configuration that may be used for the pixels of display 14 of device 10 is shown in FIG. 2. As shown in FIG. 2, display 14 may have a substrate such as substrate 24. Substrate 24 may be formed from a material such as glass or other dielectric. Anode 32 may be formed from a layer of indium tin oxide or other conductive material on the surface of substrate 30. Cathode 44 may be formed at the top of display 14. Cathode may be formed from a conductive layer such as a layer of metal that is sufficiently thin to be transparent (i.e., sufficiently transparent to allow light 46 that is emitted from display 14 to travel upward towards viewer 48).

The layers of material between cathode 44 and anode 32 form a light-emitting diode. These layers may include layers such as electron injection layer 42, electron transport layer 40, emissive layer 38, hole transport layer 36, and hole injection layer 34. Layers 42, 40, 38, 36, and 34 may be formed from organic materials. Emissive layer 38 is an electroluminescent organic layer that emits light 46 in response to applied current.

Light-emitting diodes in display 14 may have different colors. These different colors may be produced using emissive layers 38 that emit light 46 of different colors. For example, display 14 may have red display pixels each of which has an emissive layer 38 that emits light 46 that is red, may have blue display pixels each of which has an emissive layer 38 that emits light 46 that is blue, and may have green display pixels each of which has an emissive layer that emits light that is green. Emissive layer 38 (and other layers in display 14) may, if desired, be patterned by depositing these layers through a shadow mask using an evaporation tool (i.e., an evaporator). For example, red pixels formed form portions of emissive layer 38 may be formed on a display by evaporating a red emissive material with an evaporation tool while an appropriate red shadow mask is aligned with display substrate 24. The red shadow mask has an array of red pixel openings that allow red emissive material 38 to be deposited in a desired pattern on display substrate 24. Blue and green pixels may be deposited in the same way, using a blue pixel shadow mask and green pixel shadow mask, respectively.

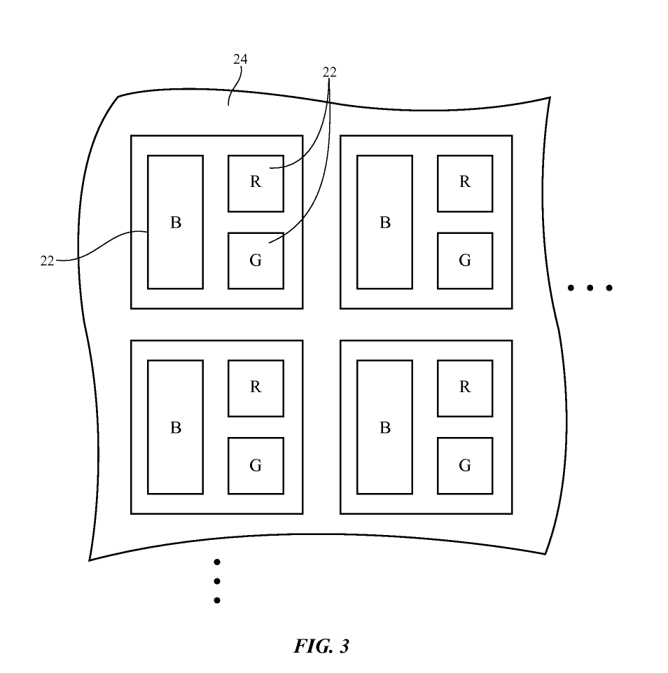

A portion of display 14 having an illustrative pattern that may be used for forming red pixels R, blue pixels B, and green pixels G is shown in FIG. 3. Red pixels R may be formed by evaporating red organic emissive material through a red shadow mask with openings aligned with the red pixel locations of FIG. 3, green pixels G may be formed by evaporating green organic emissive material through a green shadow mask with openings aligned with the green pixel locations of FIG. 3, and blue pixels B may be formed by evaporating blue organic emissive material onto substrate 24 through a blue shadow mask with openings aligned with the blue pixel locations of FIG. 3. Shadow masks with other patterns of openings may be used if desired.

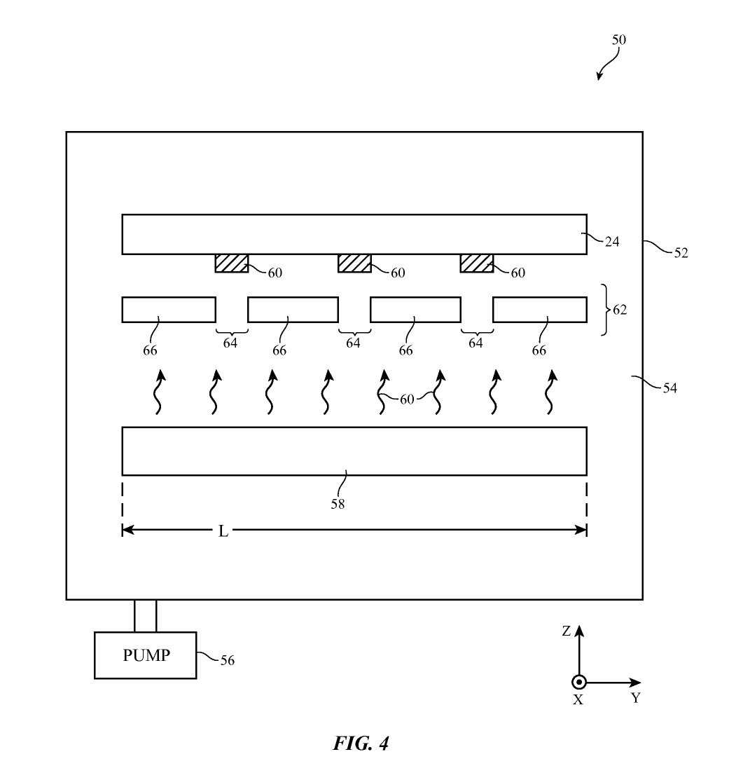

A cross-sectional side view of an evaporation tool of the type that may be used to pattern emissive layer material for red, green, and blue pixels or that may be used to deposit other materials is shown in FIG. 4. As shown in FIG. 4, evaporation tool 50 has a vacuum chamber such as chamber 52. During evaporation operations, interior 54 of chamber 52 may be evacuated of air using pump 56 (i.e., a vacuum may be created in chamber 52).

Evaporation source 58 has heating elements that heat materials to be evaporated. Source 58 may have orifices that serve as point sources emitting evaporated material. Evaporated material 60 from source 58 passes through openings 64 in metal mask layer 66 of shadow mask 62. The portions of material 60 that pass through openings 64 form deposited structures (layers) 60 on substrate 24. Openings 64 in metal mask layer 66 are arranged in a pattern appropriate for a given one of the pixel colors of FIG. 3.

Source 58 may be a linear source that is thin in lateral dimension X (i.e., into the page in the orientation of FIG. 4) and that is elongated along lateral dimension Y (i.e., across the page in the orientation of FIG. 4). Source 58 may have a rectangular footprint and may have a pair of opposing elongated edges that run along dimension Y and a pair of opposing shorter edges that run along dimension X.

Mask 62 may have a rectangular shape (i.e., a shape that matches a desired display shape for display 14). The lateral dimension L of linear source 58 along its longitudinal axis may be sufficient to cover the entire width of mask 62 and display substrate 24, as shown in FIG. 4. In dimension X, however, linear source 58 may be too narrow to cover all of mask 62 at once. Accordingly, linear source 58 may be scanned across mask 62 during evaporation operations (i.e., source 58 may be moved in a direction that is into the page in the orientation of FIG. 4).

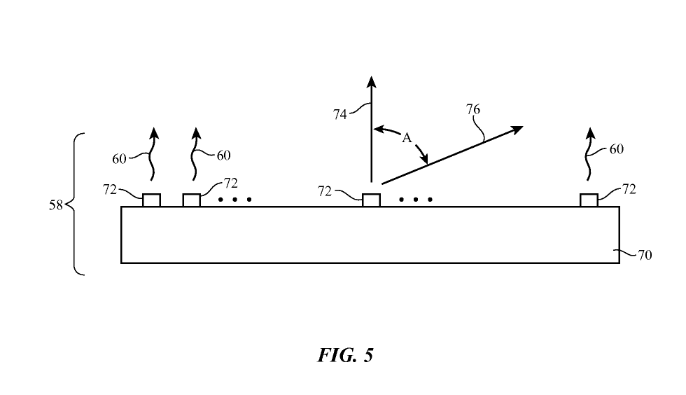

Linear source 58 may be made up of a number of discrete source elements. As shown in the side view of FIG. 5, for example, linear source 58 may have an elongated base structure such as elongated base 70. A series of separate source elements may be formed on base 70 such as source elements 72. Source elements 72 may be arranged in a linear array extending along the longitudinal axis of source 58 (i.e. parallel to dimension Y). Each source element 72 may correspond to a respective evaporation orifice (e.g., a nozzle) that serves as a point source for material 60. Source elements 72 may be distributed unevenly along the length of source 58 (e.g., there may be a greater density of source elements 72 near the ends of source 58 than near the middle of source 58).

If care is not taken, material 60 will be evaporated not only in desired vertical directions such as direction 74 towards the evaporation target (i.e., mask 62 of FIG. 4), but also in highly angled directions such as direction 76 at angle A to vertical direction 74. The presence of evaporating material 60 that is characterized by large angles A with respect to vertical direction 74 (e.g., angles of 40° or more or other suitable angle) tends to make it difficult to precisely deposit structures 60 on substrate 24 through mask 62.

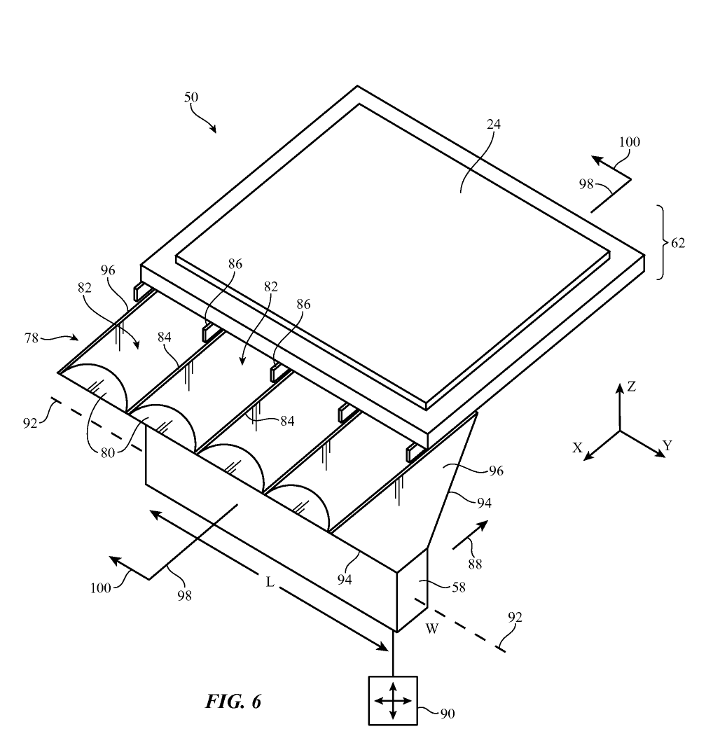

A perspective view of an illustrative evaporation tool that has features for restricting angle A for evaporated material from source 58 and thereby improving the directionality of the evaporated material and the accuracy of the deposited structures on substrate 28 is shown in FIG. 6. As shown in FIG. 6, evaporation tool 50 includes a linear source such as source 58 that is elongated along dimension Y (i.e., along longitudinal axis 92 of source 58) and that therefore has a lateral dimension L along dimension Y that is significantly larger than perpendicular lateral dimension W. As an example, L may be three or more times larger than W, may be four or more times larger than W, may be five or more times larger than W, or may be ten or more times larger than W. Because of the relatively narrow dimension W of source 58, source 58 is preferably translated along the X axis of FIG. 6 in direction 88 during evaporation operations, thereby distributing evaporated material 66 (FIG. 4) evenly across the underside of mask 62. Computer-controlled positioner 90 may be used to move source 58 in direction 88.

Evaporation control structure 78 includes angled sidewalls 94, end walls 96, and a series of inner walls 84. Angled walls 94 may be attached to the elongated edges of source 58 and may be angled outwardly from source 58. Vertical end walls 96 and vertical inner walls 84 lie in the X-Z plane of FIG. 6 Inner walls 84 divide structure 78 into a series of corresponding sections 82 along longitudinal axis 92. Each section may be associated with a different respective group of source elements 72.

The presence of walls 84 helps to prevent material 60 from being evaporated at large transverse angles A (i.e., at large angles A in the Y-Z plane with respect to vertical dimension Z), as described in connection with FIG. 5. If desired, correction plate structures such as structures 80 (e.g., a patterned horizontal plate that lies in the horizontal X-Y plane of FIG. 6), may be used to adjust the pattern of evaporated material 60 that is produced by the group of source elements 72 within each section of structure 78. In the example of FIG. 6, correction plate 80 has a series of semicircular areas each of which is mounted in a respective one of sections 82, so that correction plate 80 has scalloped inner edges. Other shapes may be used for correction plate 80 if desired. There may be a pair of correction plates 80 on structure 78 (i.e., a first correction plate 80 attached along the upper edge of a first of angled walls 94 and a second correction plate 80 attached along the opposing upper edge of a second of angled walls 94).

During evaporation operations, substrate 24 is placed on top of shadow mask 62 to receive evaporated material 60 through the openings in the metal mask layer of mask 62. If desired, mask 62 may have vertical walls 86 that are aligned with corresponding walls in structure 78 such as inner walls 84 and that therefore serve as vertical wall extensions for walls 84. Some of walls 86 may be aligned with end walls 96, if desired. Vertical walls 86 extend downwardly from mask 62 and lie in the same planes as inner walls 84 (and optionally lie in the same planes as end walls 96). As source 58 and associated structure 78 are moved in direction 88 during evaporation operations, walls 84 remain in alignment with walls 86.

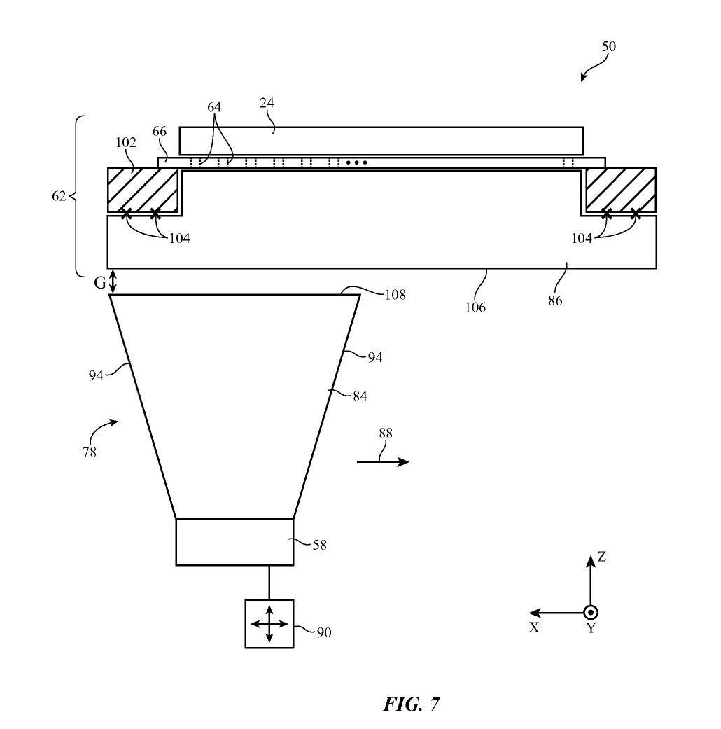

A cross-sectional side view of evaporation tool 50 of FIG. 6 taken along line 98 and viewed in direction 100 is shown in FIG. 7. As shown in FIG. 7, shadow mask 62 may include mask frame 102. Frame 102 may have a rectangular shape with an rectangular central opening. The edges of metal mask layer 66 may be supported by mask frame 102. Metal mask layer 66 may also have openings 64 in a desired pattern for depositing evaporated material from source 58 onto the lower surface of substrate 24. Welds 104 or other attachment structures may be used to attach wall extensions 86 to frame 102. A gap G may separate lower edge 106 of each vertical wall extension 86 from upper edge 108 of each corresponding vertical wall 84 of evaporation control structure 78. The size of gap G may be relatively small (e.g., 1 mm to 1 cm or other suitable size) so that the vertical walls 84 and wall extensions 86 effectively block all evaporated material with a trajectory having a large transverse angle A relative to vertical. Angled walls 94 may have an angle of about 0-45° or 5-40°, or 10-35° or other suitable orientations to prevent material from being evaporated at a large angle with respect to vertical in the X-Z plane. With this arrangement, walls 94 restrict the angular spread of evaporated material 60 in the X-Z plane and walls 84 restrict the angular spread of evaporated material 60 in the Y-Z plane.

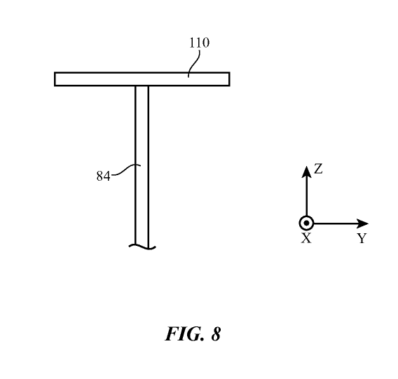

Additional control of the angular spread of evaporated material may be provided by incorporating additional structures onto walls 84 and/or 86. A cross-sectional end view of an illustrative vertical inner wall 84 that has been provided with horizontal blocking structure 110 is shown in FIG. 8. Blocking structures such as blocking structure 110 may be oriented at various angles relative to vertical wall 84 portion and/or vertical wall portion 86. The example of FIG. 8 in which structure 110 lies in a horizontal plane and is perpendicular to vertical wall 84 is merely illustrative.

The foregoing is merely illustrative and various modifications can be made by those skilled in the art without departing from the scope and spirit of the described embodiments. The foregoing embodiments may be implemented individually or in any combination.

What is claimed is:

1. An evaporation tool, comprising:
an elongated evaporation source having a longitudinal axis and a pair of elongated edges that run parallel to the longitudinal axis;
an evaporation control structure having a pair of angled walls mounted along the elongated edges and having at least one vertical inner wall that extends between the pair of angled walls and that divides the evaporation control structure into a plurality of sections; and
a positioner that moves the elongated evaporation source perpendicular to the longitudinal axis.

2. The evaporation tool defined in claim 1 further comprising a shadow mask that patterns evaporated material from the evaporation source.

3. The evaporation tool defined in claim 2 wherein the shadow mask has a vertical wall extension that is aligned with the vertical inner wall of the evaporation control structure.

4. The evaporation tool defined in claim 3 wherein the vertical wall extension and the vertical inner wall have respective edges that remain aligned as the positioner moves the elongated evaporation source perpendicular to the longitudinal axis.

5. The evaporation tool defined in claim 4 wherein the vertical wall extension and the vertical inner wall lie in a plane that is perpendicular to the longitudinal axis.

6. The evaporation tool defined in claim 5 further comprising a horizontal blocking structure attached to an edge of the vertical inner wall.

7. The evaporation tool defined in claim 6 wherein the shadow mask includes a metal shadow mask layer with an array of openings and a frame that supports edges of the metal shadow mask layer.

8. The evaporation tool defined in claim 7 wherein the vertical wall extension is attached to the frame.

9. The evaporation tool defined in claim 1 wherein the evaporation source comprises evaporation source elements and wherein each section of the evaporation control structure has a different respective group of the evaporation source elements.

10. The evaporation tool defined in claim 7 wherein the evaporation source elements are formed from respective orifices and wherein the evaporation control structure has a correction plate structure with semicircular areas that is attached to at least one of the angled walls.

11. An evaporation tool that evaporates material onto a substrate, comprising:
a shadow mask having openings through which the material is evaporated onto the substrate;
an elongated evaporation source from which the material is evaporated, wherein the elongated evaporation source is elongated along a longitudinal axis; and
an evaporation control structure having a series of vertical walls that separate the evaporation control structure into a corresponding series of sections along the longitudinal axis of the evaporation source.

12. The evaporation tool defined in claim 11 wherein the vertical walls have upper edges and wherein the shadow mask has wall extensions with edges that are aligned with the upper edges of the vertical walls.

13. The evaporation tool defined in claim 11 wherein the elongated evaporation source has a plurality of orifices that serve as point sources for the evaporated material.

14. The evaporation tool defined in claim 13 wherein the orifices extend along the longitudinal axis and wherein a different respective group of the orifices is located in each of the sections of the evaporation control structure.

15. The evaporation tool defined in claim 11 further comprising a positioner that moves the elongated evaporation source and the evaporation control structure so that the material is evaporated onto different portions of the shadow mask.

16. The evaporation tool defined in claim 15 wherein the shadow mask includes:
a rectangular frame; and
a mask layer supported by the frame, wherein the mask layer has an array of display pixel openings for forming display pixel structures.

17. The evaporation tool defined in claim 16 wherein the vertical walls have edges and wherein the shadow mask has vertical wall extensions with edges that are aligned with the edges of the vertical walls.

18. An evaporation tool for evaporating organic emissive material onto a display substrate, comprising:
a shadow mask having a frame and a metal mask layer supported within the frame, wherein the metal mask layer has openings through which the organic emissive material is evaporated onto the display substrate;
an evaporation source from which the organic emissive material is evaporated; and
an evaporation control structure attached to the evaporation source to ensure that the evaporated organic emissive material is evaporated towards the shadow mask, wherein the evaporation control structure has a plurality of sections separated by walls and wherein the evaporation source has a plurality of source orifices each of which emits a separate part of the evaporated organic emissive material and each of which is located in a respective one of the plurality of sections.

19. The evaporation tool defined in claim 18 wherein each of the walls has an upper edge that lies parallel to the shadow mask, the evaporation tool further comprising a positioner that move the evaporation source relative to the shadow mask and parallel to the upper edges.

20. The evaporation tool defined in claim 19 further comprising vertical wall extensions attached to the shadow mask, wherein each of the vertical wall extensions is aligned with a respective one of the walls in the evaporation control structure.
